(19) United States
(12) Patent Application Publication
(10) Pub. No.: US 2017/0077280 A1
(43) Pub. Date: Mar. 16, 2017

(54) SEMICONDUCTOR DEVICE AND METHOD OF MANUFACTURING A SEMICONDUCTOR DEVICE

(71) Applicant: KABUSHIKI KAISHA TOSHIBA, Tokyo (JP)

(72) Inventor: Chisato FURUKAWA, Komatsu Ishikawa (JP)

(21) Appl. No.: 15/062,209

(22) Filed: Mar. 7, 2016

(30) Foreign Application Priority Data
Sep. 11, 2015 (JP) 2015-179704

(51) Int. Cl. H01L 29/778; H01L 29/66; H01L 29/205; H01L 29/10; H01L 29/20

(52) U.S. Cl. CPC H01L 29/7787; H01L 29/1029; H01L 29/2003; H01L 29/205; H01L 29/66462

(57) ABSTRACT

A semiconductor device includes a substrate, a first layer above the substrate and including a nitride semiconductor layer of a first conductivity type, a second layer on the first layer and including a nitride semiconductor layer of the first conductivity type containing Al, an insulating film on the upper surface of the second layer in a first region of the upper surface of the second layer, a third layer on the upper surface of the second layer in a second region of the upper surface of the second layer, the third layer including a nitride semiconductor layer of a second conductivity type, the third layer including a first portion in contact with the second layer and a second portion on the first portion, and an electrode on the second portion. A width of the first portion is larger than that of the second region and that of the first portion.

### CROSS-REFERENCE TO RELATED APPLICATION

This application is based upon and claims the benefit of priority from Japanese Patent Application No. 2015-179704, filed Sep. 11, 2015, the entire contents of which are incorporated herein by reference.

### FIELD

Embodiments described herein relate generally to a semiconductor device and a method of manufacturing a semiconductor device.

### BACKGROUND

In gallium nitride-based semiconductor devices such as a high electron mobility transistor (GaN-HEMT), a two-dimensional electron gas (2DEG) layer arranged below a gate electrode may be removed or canceled in order to obtain a normally-off structure. For example, when a p type GaN layer is provided on a stack of an n type GaN layer and an n type AlGaN layer, it is possible to inject p type carriers into the n type AlGaN layer from the p type GaN layer so as to cancel the 2DEG layer generated at an interface between the n type GaN layer and the n type AlGaN layer.

When such a GaN-HEMT is manufactured, the p type GaN layer cannot be processed by wet etching, and thus is processed by dry etching. However, when dry etching is used, damage remains on a surface of the n type AlGaN layer after the p type GaN layer is etched. In addition, after the p type GaN layer is processed, heat treatment is performed in order to realize an ohmic contact between the p type GaN layer and a metal gate electrode formed thereon. However, when hydrogen diffuses from an insulating interlayer film covering the p type GaN layer to the p type GaN layer due to the heat treatment, there is a concern that the p type GaN layer may not function as a p type semiconductor.

### DESCRIPTION OF THE DRAWINGS

FIG. 1 is a cross-sectional view illustrating an example of the configuration of a semiconductor device according to the present embodiment.

FIGS. 2A to 2C are cross-sectional views illustrating an example of a method of manufacturing the semiconductor device according to the present embodiment.

FIGS. 3A and 3B are cross-sectional views illustrating the example of the method of manufacturing the semiconductor device according to the present embodiment.

### DETAILED DESCRIPTION

Embodiments provide a semiconductor device and a method of manufacturing a semiconductor device which are capable of reducing an on-resistance and achieving a stable normally-off while reducing a gate resistance.

In general, according to one embodiment, a semiconductor device includes a substrate, a first layer above the substrate and including a nitride semiconductor layer of a first conductivity type, a second layer on the first layer and including a nitride semiconductor layer of the first conductivity type containing Al, the second layer having an upper surface with a first region and a second region that is next to the first region along a first direction, an insulating film on the upper surface of the second layer in the first region of the upper surface of the second layer, a third layer on the upper surface of the second layer in the second region of the upper surface of the second layer, the third layer including a nitride semiconductor layer of a second conductivity type, the third layer including a first portion in contact with the second layer and a second portion on the first portion, and an electrode on the second portion of the third layer. A width of the first portion in the first direction is larger than a width of the second region in the first direction and a width of the first portion in the first direction.

Hereinafter, an embodiment will be described with reference to the accompanying drawings. The present embodiment does not limit the invention. In the following embodiment, a vertical direction of a semiconductor substrate indicates a relative direction when a surface on which a semiconductor element is provided is set to face upward, and may be different from a vertical direction aligned with the gravitational acceleration.

In the present embodiment described below, gallium nitride (GaN) is used as a group III nitride semiconductor. However, instead of gallium nitride (GaN), aluminum nitride (AlN) or indium nitride (InN) may be used as a group III nitride semiconductor. In the following description, it is assumed that a group III nitride semiconductor is gallium nitride (GaN). In addition, in the present embodiment, for example, an AlGaN layer is used as a group III nitride semiconductor containing Al.

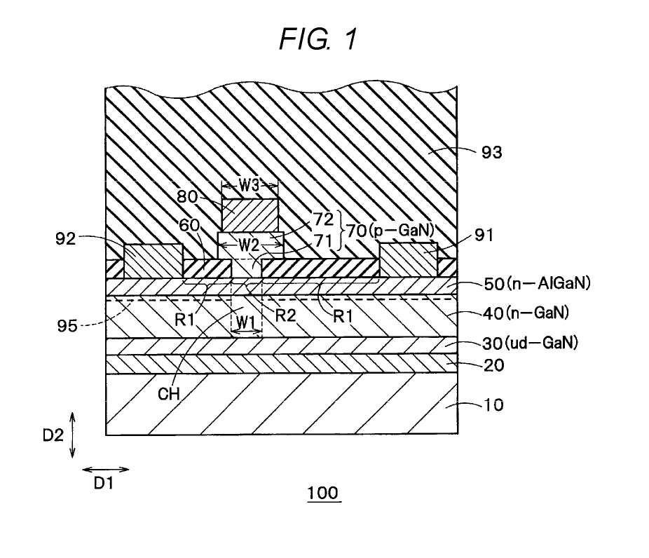

FIG. 1 is a cross-sectional view illustrating an example of the configuration of a semiconductor device 100 according to the present embodiment. The semiconductor device 100 includes a substrate 10, a buffer layer 20, an undoped GaN (ud-GaN) layer 30, an n type GaN layer 40, an n type AlGaN layer 50, an insulating film 60, a p type GaN layer 70, a gate electrode 80, a drain electrode 91, a source electrode 92, and an insulating interlayer film 93. For example, the semiconductor device 100 is a junction field effect transistor (JFET) type GaN-HEMT. In addition, wirings, contacts, and the like which are provided in or on the insulating interlayer film 93 are not shown in the drawing.

The substrate 10 is a substrate containing any one or more of sapphire, diamond, SiC, GaN, BN, Si, and Ge. For example, the substrate may be a silicon substrate, a GaN substrate, a SiC substrate, or the like. The conductivity type of the substrate 10 is not particularly limited.

The buffer layer 20 is provided on a surface (first surface) of the substrate 10. The buffer layer 20 is formed using, for example, a superlattice structure in which AlN and GaN are alternately stacked, or using a composition gradient AlGaN layer in which a content ratio of Al in AlGaN gradually decreases toward the n type GaN layer 30 from the surface of the substrate 10. Since the buffer layer 20 is interposed between the substrate 10 and a stacked structure (30, 40, and 50) warpage is suppressed. In addition, the buffer layer 20 improves the crystallizability of the stacked structure including the GaN layers 30 and 40 and the AlGaN layer 50 provided thereon.

The ud-GaN layer 30 is provided on the buffer layer 20. Here, GaN having no impurities introduced thereinto is used for the ud-GaN layer 30.

The n type GaN layer 40 serving as a first layer is provided on the ud-GaN layer 30. The n type GaN layer 40 is a GaN layer containing n type impurities (for example, carbon (C), silicon (Si), germanium (Ge), sulfur (S), or the like). The n type GaN layer 40 has a film thickness, for example, equal to or greater than 1 pm.

The n type AlGaN layer 50 serving as a second layer is provided on the n type GaN layer 40. The n type AlGaN layer 50 is an AlGaN layer containing n type impurities (for example, silicon (Si) or germanium (Ge)). The n type AlGaN layer 50 has a film thickness of, for example, 15 nm to 30 nm.

The insulating film 60 is provided in a first region R1 on an upper surface of the n type AlGaN layer 50. The first region R1 includes a region on the upper surface of the n type AlGaN layer 50 between the drain electrode 91 and a channel portion CH and is a region on the upper surface of the n type AlGaN layer 50 between the source electrode 92 and the channel portion CH. The insulating film 60 is an insulating film such as SiO₂, SiN, Al₂O₃, or ZrO. The insulating film 60 has a film thickness of, for example, 20 nm to 30 nm.

The p type GaN layer 70 as a third layer is provided in a second region R2 on the upper surface of the n type AlGaN layer 50. The p type GaN layer 70 is a GaN layer containing p type impurities (for example, magnesium (Mg)). The second region R2 is a region on the upper surface of the n type AlGaN layer 50 corresponding to the channel portion CH. In addition, the p type GaN layer 70 functions as a portion of a gate electrode.

The p type GaN layer 70 includes a first portion 71 and a second portion 72. The first portion 71 is provided in the second region R2 of the n type AlGaN layer 50. As illustrated in FIG. 1, the first portion 71 has substantially the same width W1 as a width of the second region R2 in a longitudinal section (cross section in a direction perpendicular to a channel width direction) taken along a stack direction D2 of the n type AlGaN layer 50 and the p type GaN layer 70. That is, the width W1 of the first portion 71 in a channel length direction D1 is substantially the same as the width of the second region R2 in the channel length direction D1. In addition, the first portion 71 is in the second region R2, and has substantially the same thickness as a thickness of the insulating film 60. On the other hand, the second portion 72 is provided on the first portion 71 and is provided on the insulating film 60 adjacent to the first portion 71. Therefore, the second portion 72 has a width W2 larger than the width of the second region R2 and the width W1 of the first portion 71 in the above-mentioned cross section. That is, the width W2 of the second portion 72 in the channel length direction D1 is larger than the width of the second region R2 and the width W1 of the first portion 71 in the channel length direction D1. Therefore, the p type GaN layer 70 has a substantially T shape in the cross section illustrated in FIG. 1. The thickness of the second portion 72 is not particularly limited, and is, for example, approximately 40 nm.

The gate electrode 80 serving as an electrode is provided on the second portion 72 of the p type GaN layer 70. For example, a conductive material such as Ta, TaN, Ti, TiN, W, WN, or P type polysilicon is used for the gate electrode 80. The width W2 of the second portion 72 is larger than the width of the second region R2 and the width W1 of the first portion 71, and thus it is possible to increase the width of the gate electrode 80. Therefore, the gate electrode 80 has a width W3 larger than the width of the second region R2 and the width W1 of the first portion 71 in the cross section illustrated in FIG. 1. That is, the width W3 of the gate electrode 80 in the channel length direction D1 is larger than the width of the second region R2 and the width W1 of the first portion 71 in the channel length direction D1. Thereby, it is possible to increase a contact area between the gate electrode 80 and the p type GaN layer 70 and to reduce a gate resistance of the entire gate electrode (70 and 80). In addition, the gate electrode 80 is provided on the second portion 72, and thus the width W3 of the gate electrode 80 in the channel length direction D1 is equal to or less than the width W2 of the second portion 72 in the channel length direction D1.

Here, the n type GaN layer 40 and the n type AlGaN layer 50 make up a heterostructure, and thus a two-dimensional electron gas (hereinafter, also referred to as 2DEG) layer 95 is generated at an interface between the n type GaN layer 40 and the n type AlGaN layer 50. The 2DEG layer 95 functions to reduce an electric resistance between the drain electrode 91 and the source electrode 92 and to reduce an on-resistance of the semiconductor device 100.

In the present embodiment, the 2DEG layer 95 is generated at the interface between the n type GaN layer 40 and the n type AlGaN layer 50 which are arranged below the first region R1, the drain electrode 91, and the source electrode 92, but is not generated in the channel portion CH arranged below the second region R2. This is because a potential is raised by a PN junction between the p type GaN layer 70 and the n type AlGaN layer 50 and the 2DEG layer 95 arranged below the second region R2 is depleted. Thereby, the channel portion CH having no 2DEG layer 95 is provided below the second region R2. Since the channel portion CH is provided below the second region R2, the semiconductor device 100 may serve as a JFET type GaN-HEMT having a normally-off structure. On the other hand, the 2DEG layer 95 is maintained in a current path between the drain electrode 91 and the channel portion CH and in a current path between the source electrode 92 and the channel portion CH. Therefore, when a desired gate voltage is applied to the gate electrode 80 and the p type GaN layer 70, the semiconductor device 100 is set to be in an on state, and a current may flow from the drain electrode 91 through the 2DEG layer 95 and the channel portion CH to the source electrode 92. Therefore, the semiconductor device 100 has a low resistance when set in an on state.

The channel portion CH is provided below the first portion 71 of the p type GaN layer 70, and has a channel length corresponding to the width W1 of the first portion 71. That is, the width of the channel portion CH in the channel length direction D1 is about W1. Accordingly, the channel length of the semiconductor device 100 is smaller than that of the second portion 72 of the p type GaN layer 70. Thereby, it is possible to further reduce the on-resistance of the semiconductor device 100. On the other hand, the gate electrode 80 is provided on the second portion 72 of the p type GaN layer 70, and has the width W3 larger than the width W1 of the first portion 71. Thereby, it is possible to make a contact area between the p type GaN layer 70 and the gate electrode 80 relatively large. That is, according to the present embodiment, it is possible to reduce the on-resistance by reducing the channel length while reducing the gate resistance by increasing the contact area between the metal gate electrode 80 and the p type GaN layer 70. In addition, a distance between a source and a drain is reduced by reducing the channel length of the semiconductor device 100, which makes the element smaller. Further, the second portion 72 of the p type GaN layer 70 is wider than the first portion 71, and thus an electric field on the both sides of the second portion 72 is applied to an interface between the insulating film 60 and the n type AlGaN layer 50 through the insulating film 60 when a voltage is applied to the gate electrode 80. Thereby, it is possible to reduce an amount of charge trapped at the interface between the insulating film 60 and the n type AlGaN layer 50 in the vicinity of both ends of the first portion 71 during the operation of the semiconductor device 100.

As described above, according to the present embodiment, the p type GaN layer 70 which is a portion of the gate electrode has the substantially T shape, and includes the first portion 71 having a relatively small width in the channel length direction D1 and the second portion 72 having a relatively large width in the channel length direction D1. Thereby, it is possible to reduce the channel length while increasing the contact area between the gate electrode 80 and the p type GaN layer 70. As a result, it is possible to reduce a gate resistance and an on-resistance.

In addition, in the semiconductor device 100 according to the present embodiment, the p type GaN layer 70 has a substantially T shape, and thus it is possible to suppress a decrease in the concentration of p type carriers of the p type GaN layer 70 in a manufacturing process. This will be described later together with a manufacturing method.

Next, the method of manufacturing the semiconductor device 100 according to the present embodiment will be described.

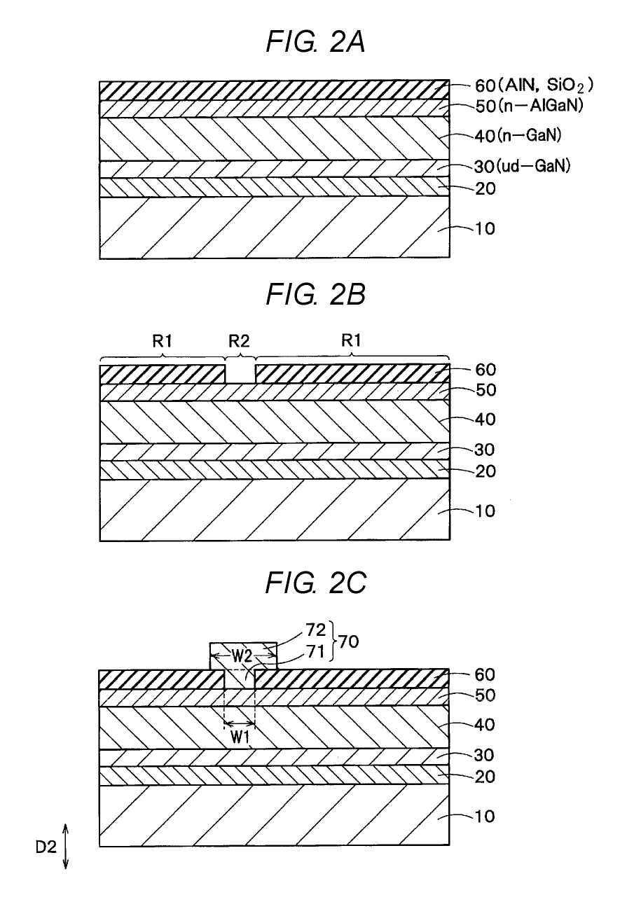

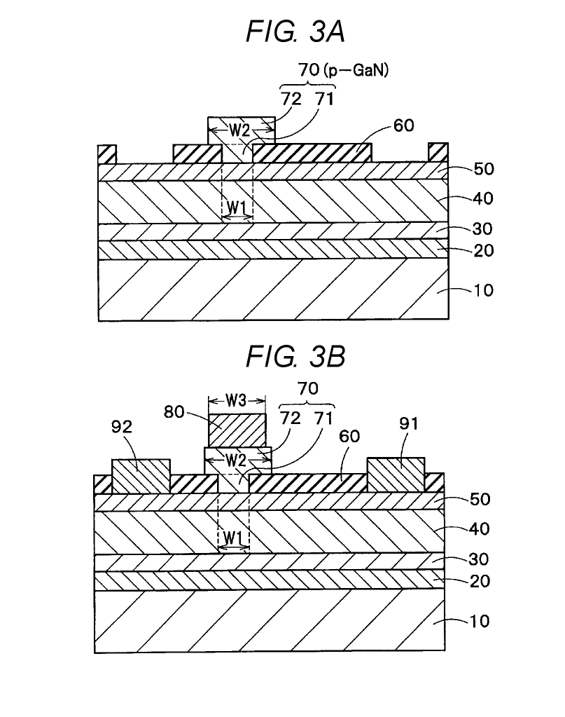

FIG. 2A to FIG. 3B are cross-sectional views illustrating an example of the method of manufacturing the semiconductor device 100 according to the present embodiment. The method of manufacturing the semiconductor device 100 will be described with reference to FIG. 2A to FIG. 3B.

First, the buffer layer 20 is formed on the substrate 10 using a metal organic chemical vapor deposition (MOCVD) method. As described above, the buffer layer 20 has the superlattice structure of AlN and GaN or the composition gradient AlGaN layer. For example, when the superlattice structure of AlN and GaN is formed on the substrate 10, AlN layers and GaN layers may be alternately stacked on the substrate 10 in order of the AlN layer, the GaN layer, the AlN layer, the GaN layer, the AlN layer, the GaN layer, . . . . For example, when the composition gradient AlGaN layer is formed on the substrate 10, the content of Al in AlGaN is first set to 100%, and AlGaN is deposited while gradually decreasing the content of Al. In addition, the content of Al in the uppermost portion of the buffer layer 20 may be 0%.

Next, the ud-GaN layer 30 is deposited on the buffer layer 20 using a MOCVD method. At this time, GaN is deposited without impurities being added.

Next, the n type GaN layer 40 is deposited using a MOCVD method. At this time, GaN is deposited while n type impurities (for example, Si or Ge) are added.

Next, the n type AlGaN layer 50 is deposited on the n type GaN layer 40 using a MOCVD method. At this time, GaN is deposited while n type impurities (for example, Si or Ge) and Al are added. In addition, the buffer layer 20, the ud-GaN layer 30, the n type GaN layer 40, and the n type AlGaN layer 50 may be consecutively grown in the same MOCVD device.

Next, the insulating film 60 is deposited on the n type AlGaN layer 50. The insulating film 60 is a material for suppressing the epitaxial growth of the p type GaN layer 70, and is an insulating film such as SiO₂, SiN, Al₂O₃, or ZrO. Thereby, a stacked structure illustrated in FIG. 2A is obtained.

Next, as illustrated in FIG. 2B, the insulating film 60 arranged in the second region R2 is removed using a lithography technique and an etching technique. The insulating film 60 in the first region R1 is left as it is. The insulating film 60 functions as a mask layer in the subsequent epitaxial process. That is, the insulating film 60 covers the n type AlGaN layer 50 in the first region R1, and thus the p type GaN layer 70 is not epitaxially grown in the first region R1. On the other hand, the p type GaN layer 70 can be selectively epitaxially grown in the second region R2 having no insulating film 60.

Next, the p type GaN layer 70 is epitaxially grown using the insulating film 60 as a mask. Thereby, the p type GaN layer 70 is selectively epitaxially grown in the second region R2 without grown on the insulating film 60 in the first region R1 on the surface of the n type AlGaN layer 50. At this time, the p type GaN layer 70 is grown in a direction substantially perpendicular to the upper surface of the n type AlGaN layer 50 in the second region R2, and is formed to have a thickness which is substantially the same as that of the insulating film 60. Thereby, as illustrated in FIG. 2C, the first portion 71 having the width W1 which is substantially the same as the width of the second region R2 in the cross section in the stack direction D2 is formed on the n type AlGaN layer 50. Thereafter, the p type GaN layer 70 is grown not only in a direction substantially perpendicular to the upper surface of the n type AlGaN layer 50 but also in a direction substantially parallel thereto (horizontal direction). Thereby, the p type GaN layer 70 laterally spreads to the upper surface of the insulating film 60 in the vicinity of the second region R2, and is also formed on the insulating film 60 adjacent to the first portion 71. That is, as illustrated in FIG. 2C, the second portion having the width W2 which is larger than the width of the second region R2 and the width W1 of the first portion 71 in the cross section in the stack direction D2 is formed on the first portion 71. Thereby, the p type GaN layer 70 has a substantially T shape as illustrated in FIG. 2C. The p type GaN layer 70 is epitaxially grown while p type impurities (for example, magnesium) are added thereto.

Next, as illustrated in FIG. 3A, the insulating film 60 arranged in a source electrode formation region and a drain electrode formation region is removed using a lithography technique and an etching technique.

Next, a conductive material is deposited on the p type GaN layer 70, the source electrode formation region, and the drain electrode formation region. The conductive material is a conductive material such as Ta, TaN, Ti, TiN, W, WN, or P type polysilicon.

Next, the conductive material is processed using a lithography technique and an etching technique. Thereby, the gate electrode 80 is formed on the p type GaN layer 70, the drain electrode 91 is formed in the drain electrode formation region, and the source electrode 92 is formed in the source electrode formation region. Here, the gate electrode 80 is processed to have the width W3 which is larger than the width of the second region R2 and the width W1 of the first portion 71 and is smaller than the width W2 of the p type GaN layer 70 in the cross section in the stack direction D2 (cross section in the direction perpendicular to the channel width direction).

Next, heat treatment (ohmic annealing) is performed in order to bring the p type GaN layer 70 and the gate electrode 80 into ohmic contact with each other. For example, the heat treatment is performed at a temperature of approximately 800° C. to 900° C. by a rapid thermal annealing (RTA) method. Thereby, the p type GaN layer 70 and the gate electrode 80 come into ohmic contact with each other.

Thereafter, the manufacture of the semiconductor device 100 illustrated in FIG. 1 is completed by forming the insulating interlayer film 93, contacts, and wirings (not shown). In addition, the insulating film 60 is removed by a wet etching method after the p type GaN layer 70 is formed, and an insulating interlayer film may be deposited thereon again. On the other hand, the insulating film 60 may be left as an insulating interlayer film as it is. In this case, it is possible to prevent nitrogen from being extracted from the n type AlGaN layer 50 arranged below the insulating film 60.

In this manner, according to the present embodiment, the p type GaN layer 70 is selectively epitaxially grown on the second region R2 of the n type AlGaN layer 50, and is formed such that the width W2 of the second portion 72 is larger than the width W1 of the first portion 71 in the cross section in the stack direction D2 (cross section in the direction perpendicular to the channel width direction). In this manner, the p type GaN layer 70 is formed by selective epitaxial growth without using dry etching such as a reactive ion etching (RIE) method. Therefore, the surface of the n type AlGaN layer 50 is not influenced by dry etching, and thus it is possible to maintain a state with little damage. Thereby, it is possible to suppress an increase in leakage current, a reduction in breakdown voltage, an increase in contact resistance, and the like.

In addition, the p type GaN layer 70 is formed by selective epitaxial growth, and thus the p type GaN layer 70 is formed to have the substantially T shape and is formed such that the width W2 of the second portion 72 is larger than the width W1 of the first portion 71. Thereby, the gate electrode 80 formed on the p type GaN layer 70 may be formed to have the relatively large width W3. As a result, it is possible to increase an area of an ohmic contact between the gate electrode 80 and the p type GaN layer 70 while maintaining the width W1 of the first portion 71. Thereby, it is possible to reduce the on-resistance of the semiconductor device 100.

Further, in the above-mentioned ohmic annealing, the side surface of the first portion 71 of the p type GaN layer 70 is covered with the insulating film 60, and a portion of the upper surface and the side surface of the second portion 72 of the p type GaN layer 70 is not covered with the insulating film but is exposed. Therefore, an amount of hydrogen entering the p type GaN layer 70 during the ohmic annealing is relatively small.

When the n type GaN layer 40, the n type AlGaN layer 50, and the p type GaN layer 70 are consecutively grown as in the related art, the p type GaN layer 70 is required to be processed using a lithography technique and a dry etching technique. In this case, the surface of the n type AlGaN layer 50 is damaged, and it is necessary to cover a portion of the upper surface and the side surface of the p type GaN layer 70 with an insulating film (not shown) in order to form a gate electrode on the upper surface of the p type GaN layer 70 after the p type GaN layer 70 is processed. The insulating film contains, for example, SiO₂, SiN, Al₂O₃, or AlN, and contains hydrogen. For this reason, after the gate electrode is formed, hydrogen of the insulating film diffuses to the p type GaN layer 70 during ohmic annealing. The hydrogen is coupled to carriers (magnesium) within the p type GaN layer 70, which results in a reduction in the concentration of the carriers of the p type GaN layer 70. Thus, when a portion of the upper surface and the side surface of the p type GaN layer 70 are covered with an insulating film during the ohmic annealing as described above, hydrogen contained in the insulating film tends to diffuse to the p type GaN layer 70. In addition, since the upper surface of the p type GaN layer 70 is capped with the gate electrode, hydrogen entering the p type GaN layer 70 is not likely to be extracted from the p type GaN layer 70. Therefore, the concentration of carriers of the p type GaN layer 70 is decreased, and thus the capacity of the p type GaN layer 70 to function as a p type deteriorates. When the p type GaN layer 70 deteriorates, it is not possible to sufficiently cancel the 2DEG layer 95 arranged below the second region R2, and thus there is a concern that the semiconductor device 100 may not be in a normally-off state. That is, there is a concern that the semiconductor device 100 may not functions as a JFET.

On the other hand, in the present embodiment, the p type GaN layer 70 is selectively grown after forming the insulating film 60, instead of being consecutively grown together with the n type GaN layer 40 and the n type AlGaN layer 50. In this case, the side surface of the first portion 71 of the p type GaN layer 70 is covered with the insulating film 60, and the upper surface of the second portion 72 is capped with the gate electrode 80. The side surface of the second portion 72 of the p type GaN layer 70 is not covered with the insulating film but is exposed. Therefore, the amount of hydrogen entering the p type GaN layer 70 is relatively small during ohmic annealing. In addition, even when hydrogen enters the p type GaN layer 70, the hydrogen is easily extracted from the second portion 72 of the p type GaN layer 70. Thereby, it is possible to suppress a decrease in the concentration of carriers of the p type GaN layer 70 and to suppress a deterioration in the functioning of the p type GaN layer 70 as a p type. That is, the semiconductor device 100 is in a normally-off state and can function as a JFET.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first layer above the substrate and including a nitride semiconductor layer of a first conductivity type;
a second layer on the first layer and including a nitride semiconductor layer of the first conductivity type containing Al, the second layer having an upper surface with a first region and a second region that is next to the first region along a first direction;
an insulating film on the upper surface of the second layer in the first region of the upper surface of the second layer;
a third layer on the upper surface of the second layer in the second region of the upper surface of the second layer, the third layer including a nitride semiconductor layer of a second conductivity type, the third layer including a first portion in contact with the second layer and a second portion on the first portion, wherein a width of the first portion in the first direction is larger than the width of the second region in the first direction and a width of the first portion in the first direction; and
an electrode on the second portion of the third layer.

2. The device according to claim 1, wherein
the first portion has a thickness which is substantially the same as a thickness of the insulating film, and
the second portion covers the first portion and the insulating film adjacent to the first portion.

3. The device according to claim 1, wherein the electrode has a width in the first direction larger than the width of the second region in the first direction and the width of the first portion in the first direction.

4. The device according to claim 1, wherein the third layer has a substantially T shape in cross-section when the cross-section is viewed along a second direction orthogonal to the first direction and a stack direction of the second layer and the third layer.

5. The device according to claim 4,
wherein the first layer is an n type GaN layer,
wherein the second layer is an n type AlGaN layer, and
wherein the third layer is a p type GaN layer.

6. The device according to claim 5, further comprising a source electrode on the second layer and a drain electrode on the second layer, wherein the insulating film is between the first portion of the third layer and the source electrode and between the first portion of the third layer and the drain electrode.

7. The device according to claim 6, further comprising
a buffer layer on the substrate; and
an undoped GaN layer on the buffer layer so as to be located between the buffer layer and the first layer.

8. The device according to claim 1, wherein the electrode is a gate electrode of a normally-off high electron mobility transistor.

9. A method of manufacturing a semiconductor device, the method comprising:
forming a first layer including a nitride semiconductor layer of a first conductivity type above a surface of a substrate;
forming a second layer including a nitride semiconductor layer of the first conductivity type containing Al on the first layer, the second layer having an upper surface with a first region and a second region that is next to the first region along a first direction;
forming an insulating film on the upper surface of the second layer in the first region of the upper surface of the second layer;
forming a third layer by epitaxially growing a nitride film semiconductor layer of a second conductivity type on the upper surface of the second layer in the second region of the upper surface of the second layer, until an upper surface of the third layer is higher than an upper surface of the insulating layer; and
forming an electrode on the third layer.

10. The method according to claim 9, wherein the third layer is epitaxially grown on the upper surface of the second layer until the third layer includes a first portion in contact with the second layer and a second portion in contact with the upper surface of the insulating film.

11. The method according to claim 9, wherein a width of the first portion in the first direction is larger than the width of the second region in the first direction and the width of the first portion in the first direction.

12. The method according to claim 11, wherein
the first portion has a thickness which is substantially the same as a thickness of the insulating film, and
the second portion covers the first portion and the insulating film adjacent to the first portion.

13. The method according to claim 11, wherein the electrode has a width in the first direction larger than the width of the second region in the first direction and the width of the first portion in the first direction.

14. The method according to claim 11, wherein the third layer has a substantially T shape in cross-section when the cross-section is viewed along a second direction orthogonal to the first direction and a stack direction of the second layer and the third layer.

15. The method according to claim 14,
wherein the first layer is an n type GaN layer,
wherein the second layer is an n type AlGaN layer, and
wherein the third layer is a p type GaN layer.

16. The method according to claim 15, further comprising:
forming a source electrode on the second layer and a drain electrode on the second layer, wherein
the insulating film is between the first portion of the third layer and the source electrode and between the first portion of the third layer and the drain electrode.

17. The method according to claim 16, further comprising
prior to forming the first layer, forming a buffer layer on the substrate, and an undoped GaN layer on the buffer layer, wherein
the first layer is formed on the undoped GaN layer.

18. The method according to claim 9, wherein the electrode is a gate electrode of a normally-off high electron mobility transistor.
